(19) United States
(12) Patent Application Publication
(10) Pub. No.: US 2020/0411330 A1
(43) Pub. Date: Dec. 31, 2020

(54) METHOD OF MANUFACTURING SEMICONDUCTOR DEVICE, SUBSTRATE PROCESSING APPARATUS, AND RECORDING MEDIUM

(71) Applicant: KOKUSAI ELECTRIC CORPORATION, Tokyo (JP)

(72) Inventors: Ryosuke YOSHIDA, Toyama-shi (JP); Yukinao KAGA, Toyama-shi (JP)

(73) Assignee: KOKUSAI ELECTRIC CORPORATION, Tokyo (JP)

(21) Appl. No.: 17/015,637

(22) Filed: Sep. 9, 2020

Related U.S. Application Data
(63) Continuation of application No. PCT/JP2019/009380, filed on Mar. 8, 2019.

(30) Foreign Application Priority Data
Mar. 30, 2018 (JP) 2018-067696

(51) Int. Cl. H01L 21/3205; H01L 21/673; C23C 16/455; C23C 16/52; C23C 16/34

(52) U.S. Cl. CPC H01L 21/32051; H01L 21/67303; C23C 16/45502; C23C 16/34; C23C 16/45544; C23C 16/52; C23C 16/45527

(57) ABSTRACT

There is provided a technique that includes (a) supplying a precursor gas and an inert gas to a substrate in a process chamber, (b) removing the precursor gas remaining in the process chamber by supplying the inert gas to the substrate in a state where the supply of the precursor gas is stopped, (c) supplying a reaction gas and the inert gas to the substrate, and (d) removing the reaction gas remaining in the process chamber by supplying the inert gas to the substrate in a state where the supply of the reaction gas is stopped, wherein (d) includes a timing at which a flow rate of the inert gas becomes lower than a flow rate of the inert gas supplied in (c).

### CROSS-REFERENCE TO RELATED APPLICATION

The application is a Bypass Continuation Application of PCT International Application No. PCT/JP2019/009380, filed on Mar. 8, 2019 and designating the United States, the international application being based upon and claiming the benefit of priority from Japanese Patent Application No. 2018-067696, filed on Mar. 30, 2018, the entire content of which is incorporated herein by reference.

### TECHNICAL FIELD

The present disclosure relates to a method of manufacturing a semiconductor device, a substrate processing apparatus, and a recording medium.

### BACKGROUND

As a process of manufacturing a semiconductor device, there is a process of forming a film on a substrate accommodated in a process chamber is performed. As an example of the film to be formed, there may be a thin film such as a titanium nitride film (TiN film) or the like.

### SUMMARY

When forming a thin film on a substrate, it may be required to control the in-plane film thickness distribution of the thin film according to the surface area and the electrical characteristics of the substrate.

Some embodiments of the present disclosure provide a technique for controlling in-plane film thickness distribution of a thin film according to the surface area and the electrical characteristics of a substrate when forming the thin film on the substrate.

According to embodiments of the present disclosure, there is provided a technique that includes (a) supplying a precursor gas and an inert gas to a substrate in a process chamber, (b) removing the precursor gas remaining in the process chamber by supplying the inert gas to the substrate in a state where the supply of the precursor gas is stopped, (c) supplying a reaction gas and the inert gas to the substrate, and (d) removing the reaction gas remaining in the process chamber by supplying the inert gas to the substrate in a state where the supply of the reaction gas is stopped, wherein (d) includes a timing at which a flow rate of the inert gas becomes lower than a flow rate of the inert gas supplied in (c).

### BRIEF DESCRIPTION OF DRAWINGS

FIG. 1 is a schematic view showing a concept of the present disclosure.

FIG. 2 is a schematic configuration view of a vertical process furnace of a substrate processing apparatus suitably used in an embodiment of the present disclosure, in which a portion of the process furnace is illustrated in a vertical cross-sectional view.

FIG. 3 is a schematic configuration view of the vertical process furnace of the substrate processing apparatus suitably used in an embodiment of the present disclosure, in which a portion of the process furnace is illustrated in a cross-sectional view taken along line X-X in FIG. 2.

FIG. 4 is a schematic configuration view of a controller of the substrate processing apparatus suitably used in an embodiment of the present disclosure, in which a control system of the controller is illustrated in a block diagram.

FIG. 5 is a diagram showing a gas supply timing in an embodiment of the present disclosure.

FIG. 6 is a diagram showing an experimental result in an embodiment of the present disclosure.

### DETAILED DESCRIPTION

With recent miniaturization and the like, when forming a thin film on a substrate, there is desire to control the in-plane film thickness distribution of the thin film in the central portion and the outer peripheral portion of the substrate surface. For example, as device miniaturization progresses, since the film thickness of a conductor film, a semiconductor film, an insulating film, and the like greatly affects the electrical characteristics, there is a demand to improve the in-plane uniformity. In addition, there is also a demand to adjust the in-plane uniformity to a desired value in accordance with the surface area and the electrical characteristics of the substrate.

As a film-forming method of forming (depositing) a thin film on a substrate, there is a method of forming a thin film on a substrate in a process chamber in which the substrate is accommodated, the method including repeatedly performing (a) forming an adsorption layer of a precursor gas by supplying and adsorbing a precursor gas on the substrate, (b) thereafter substituting (removing) the precursor gas remaining in the process chamber by supplying an inert gas, (c) subsequently forming a thin film layer by supplying a reaction gas that causes a chemical reaction with the adsorption layer of the precursor gas, and (d) thereafter substituting the reaction gas remaining in the process chamber by supplying an inert gas. In (d), when a large amount of the inert gas is supplied to the process chamber, the reaction gas in a gas phase may be substituted entirely and uniformly in the substrate surface by the inert gas, thereby forming a thin film having the same film thickness in the entire surface. However, as the surface area of the substrate increases with the progress of miniaturization, since the precursor gas and the reaction gas are not supplied up to the central portion, a film thickness of the outer peripheral portion of the substrate becomes thick and a film thickness of the central portion of the substrate becomes thin, which results in poor in-plane uniformity (loading effect), or a desired in-plane uniformity may not be obtained.

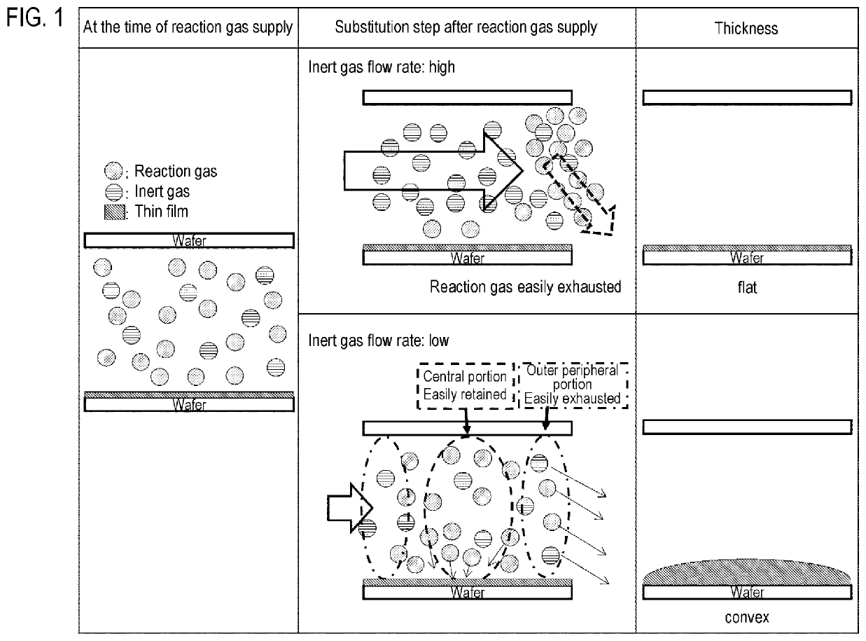

Therefore, the present inventors have conducted careful research and found that when the reaction gas is substituted in (d), by adjusting and optimizing the flow rate of the inert gas, a film thickness distribution can be changed in the central portion of the substrate and the outer peripheral portion thereof. For example, in FIG. 1, when a plurality of substrates (wafers) are arranged and processed, if the reaction gas and the inert gas are supplied to the substrate on which the thin film is being deposited, the reaction gas and the inert gas coexist between the substrates. In the substitution step after the reaction gas is supplied, if the supply flow rate of the inert gas is increased, the reaction gas is easily exhausted, thereby obtaining a film having good in-plane uniformity in which the film thickness is flat in the surface. On the other hand, if the supply flow rate of the inert gas is reduced in the substitution step after the reaction gas is supplied, the reaction gas can be substituted because the inert gas exists in the outer peripheral portion of the substrate. However, since an amount of the inert gas is small in the central portion of the substrate, the rate at which the reaction gas can be substituted is reduced, and thus the reaction gas tends to retain. Although the reaction gas can be efficiently removed at the outer peripheral portion of the substrate, the reaction gas on the substrate cannot be removed because an amount of the inert gas is small in the central portion of the substrate. A concentration gradient of the reaction gas is temporarily generated in the surface of the substrate, so that there becomes a state that the concentration of the reaction gas is high in the central portion of the substrate and is low in the outer peripheral portion of the substrate. During the same period, the precursor gas adsorbed on the substrate surface easily reacts at the central portion of the substrate and hardly reacts at the outer peripheral portion of the substrate. In this case, it is possible to obtain a thin film having a convex film thickness distribution in which the outer peripheral portion is thin (film thickness is low) and the central portion is thick (film thickness is high). This effect is particularly remarkable when forming a film on a patterned substrate having a large surface area. The details will be described below.

### First Embodiment

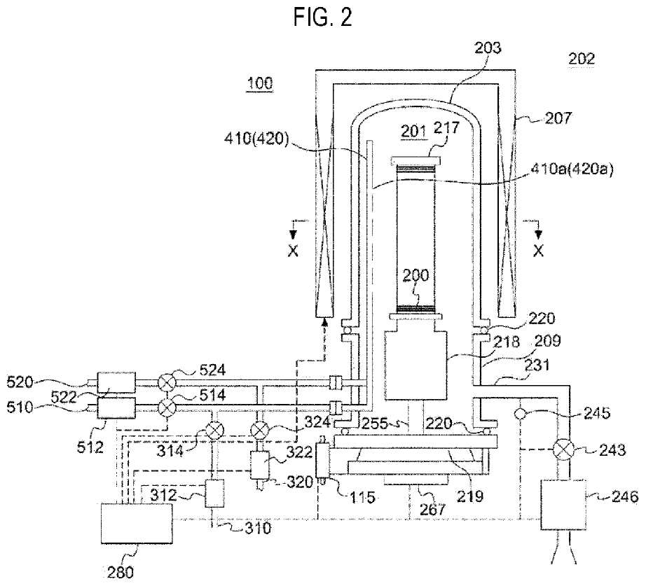

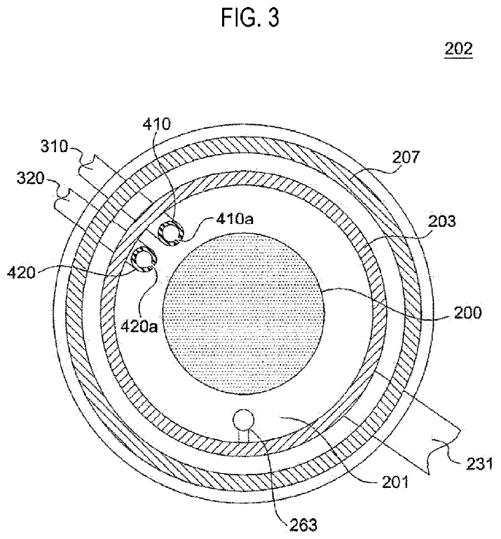

An example of an embodiment will now be mainly described with reference to FIGS. 2 to 4.

### (1) Configuration of Process Furnace

A process furnace 202 includes a heater 207 as a heating means (a heating mechanism or a heating system). The heater 207 has a cylindrical shape and is supported by a heat base (not shown) serving as a support plate so as to be vertically installed.

A reaction tube 203 forming a reaction vessel (a process vessel) is disposed inside the heater 207 to be concentric with the heater 207. The reaction tube 203 is made of, for example, a heat resistant material such as quartz (SiO₂), silicon carbide (SiC) or the like, and has a cylindrical shape with its upper end closed and its lower end opened. A manifold (inlet flange) 209 is disposed to be concentric with the reaction tube 203 under the reaction tube 203. The manifold 209 is made of, for example, a metal material such as stainless steel (SUS: Steel Use Stainless) or the like, and has a cylindrical shape with both of its upper and lower ends opened. The upper end portion of the manifold 209 is engaged with the lower end portion of the reaction tube 203 so as to support the reaction tube 203. An O-ring 220a serving as a seal member is installed between the manifold 209 and the reaction tube 203. As the manifold 209 is supported by the heater base, the reaction tube 203 is in a state of being vertically installed. The process vessel (reaction vessel) mainly includes the reaction tube 203 and the manifold 209. A process chamber 201 is formed in a hollow cylindrical portion of the process vessel.

The process chamber 201 is configured to be capable of accommodating wafers 200 as substrates in a state where the wafers 200 are arranged in a horizontal posture and in multiple stages along a vertical direction by a boat 217 to be described later.

Nozzles 410 and 420 are installed in the process chamber 201 so as to penetrate through a sidewall of the manifold 209. Gas supply pipes 310 and 320 as gas supply lines are connected to the nozzles 410 and 420, respectively.

Mass flow controllers (MFCs) 512 and 522, which are flow rate controllers (flow rate control parts), and valves 314 and 324, which are opening/closing valves, are installed to the gas supply pipes 310 and 320 sequentially from the upstream side, respectively. Gas supply pipes 510 and 520 for supplying an inert gas are connected to the gas supply pipes 310 and 320 at the downstream side of the valves 314 and 324, respectively. MFCs 512 and 522, which are flow rate controllers (flow rate control parts), and valves 514 and 524, which are opening/closing valves, are installed to the gas supply pipes 510 and 520 sequentially from the upstream side, respectively.

The nozzles 410 and 420 are configured as L-shaped long nozzles and their horizontal portions are provided to pass through the sidewall of the manifold 209. The vertical portions of the nozzles 410 and 420 are provided to be vertically erected toward an upper portion (upper portion of the arrangement direction of the wafers 200) along the inner wall of the reaction tube 203 (i.e., to be vertically erected from one end side of the wafer arrangement region to the other end side thereof) in an annular space formed between the inner wall of the reaction tube 203 and the wafers 200. That is, the nozzles 410 and 420 are installed in a region horizontally surrounding the wafer arrangement region in which the wafers 200 are arranged at a lateral side of the wafer arrangement region, along the wafer arrangement region.

Gas supply holes 410a and 420a for supplying a gas are formed in the side surfaces of the nozzles 410 and 420 along the arrangement direction of the wafers 200 so as to correspond to the substrate arrangement region where the wafers 200 are arranged. The gas supply holes 410a and 420a are opened so as to face the center of the reaction tube 203. The gas supply holes 410a and 420a are formed from a lower portion of the reaction tube 203 to an upper portion thereof to have the same aperture area at the same aperture pitch. However, the gas supply holes 410a and 420a are not limited to the above-described form. For example, the aperture area may be gradually increased from the lower portion of the reaction tube 203 to the upper portion thereof. This can make the flow rate of the gas supplied from the gas supply holes 410a and 420a more uniform.

A precursor gas as a process gas is supplied from the gas supply pipe 310 into the process chamber 201 via the MFC 312, the valve 314, and the nozzle 410. An example of the precursor gas may include a titanium tetrachloride (TiCl₄) gas as a titanium-containing precursor (Ti-containing precursor gas or Ti-containing gas), which is a metal-containing precursor (metal-containing gas) containing titanium (Ti) which is a metal element. When the term “precursor” is used in the present disclosure, it may mean a “liquid precursor in a liquid state”, a “precursor gas in a gaseous state”, or both.

As a process gas, for example, a nitriding gas (nitriding agent or nitriding precursor) as a reaction gas, which is a N-containing gas containing nitrogen (N), is supplied from the gas supply pipe 320 into the process chamber 201 via the nozzle 420. An example of the N-containing gas may include an ammonia gas (NH₃ gas).

As an inert gas, for example, a nitrogen (N₂) gas is supplied from the gas supply pipes 510 and 520 into the process chamber 201 via the MFCs 512 and 522, the valves 514 and 524, and the nozzles 410 and 420, respectively.

When a compound such as TiCl₄, which is in a liquid state at room temperature and normal pressure, is used as the process gas, TiCl₄ in the liquid state is vaporized by a vaporization system such as a vaporizer or a bubbler, and then is supplied as a TiCl₄ gas into the process chamber 201.

A process gas supply system mainly includes the gas supply pipes 310 and 320, the MFCs 312 and 322, and the valves 314 and 324. The nozzles 410 and 420 may be included in the process gas supply system. The process gas supply system may be simply referred to as a gas supply system.

A precursor gas supply system mainly includes the gas supply pipe 310, the WC 312, and the valve 314. The nozzle 410 may be included in the precursor gas supply system. When a metal-containing gas is allowed to flow from the gas supply pipe 310, the precursor gas supply system may be referred to as a metal-containing gas supply system. When a TiCl₄ gas is allowed to flow from the gas supply pipe 310, the metal-containing gas supply system can also be referred to as a TiCl₄ gas supply system.

A reaction gas supply system mainly includes the gas supply pipe 320, the WC 322, and the valve 324. The nozzle 420 may be included in the reaction gas supply system. When a nitriding gas, which is a N-containing gas, is allowed to flow from the gas supply pipe 320, the reaction gas supply system may be referred to as a N-containing gas supply system or a nitriding gas supply system. When an NH₃ gas is allowed to flow from the gas supply pipe 320, the N-containing gas supply system can also be referred to as an NH₃ gas supply system.

An inert gas supply system mainly includes the gas supply pipes 510 and 520, the MFCs 512 and 522, and the valves 514 and 524.

An exhaust pipe 231 for exhausting an internal atmosphere of the process chamber 201 is installed in the reaction tube 203. A pressure sensor 245, which is a pressure detector (pressure detecting part) for detecting an internal pressure of the process chamber 201, an auto pressure controller (APC) valve 243, and a vacuum pump 246 as a vacuum-exhausting device are connected to the exhaust pipe 231 sequentially from the upstream side. The APC valve 243 is configured to perform or stop a vacuum-exhaust operation in the process chamber 201 by opening or closing the valve at a state where the vacuum pump 246 is actuated, and is also configured to adjust the internal pressure of the process chamber 201 by adjusting an opening degree of the valve at a state where the vacuum pump 246 is actuated. An exhaust system mainly includes the exhaust pipe 231, the APC valve 243, and the pressure sensor 245. The vacuum pump 246 may be included in the exhaust system.

A seal cap 219, which serves as a furnace opening cover configured to hermetically seal a lower end opening of the manifold 209, is installed under the manifold 209. The seal cap 219 is configured to contact the lower end of the manifold 209 from the lower side in the vertical direction. The seal cap 219 is made of, for example, a metal material such as stainless steel (SUS) or the like, and is formed in a disc shape. An O-ring 220b, which is a seal member making contact with the lower end of the manifold 209, is installed on an upper surface of the seal cap 219. A rotation mechanism 267 configured to rotate the boat 217 to be described later is installed at the opposite side of the seal cap 219 from the process chamber 201. A rotary shaft 255 of the rotation mechanism 267, which penetrates through the seal cap 219, is connected to the boat 217. The rotation mechanism 267 is configured to rotate the wafers 200 by rotating the boat 217. The seal cap 219 is configured to be vertically moved up and down by a boat elevator 115 which is an elevating mechanism vertically installed outside the reaction tube 203. The boat elevator 115 is configured so as to load/unload the boat 217 into/out of the process chamber 201 by moving the seal cap 219 up and down. The boat elevator 115 is configured as a transfer device (transfer mechanism) which transfers the boat 217, i.e., the wafers 200, into/out of the process chamber 201.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. As such, the boat 217 is configured to arrange the wafers 200 to be spaced apart from each other. A ceiling plate 215 is installed at a ceiling portion of the boat 217. The boat 217 is made of a heat resistant material such as quartz or SiC. Heat insulating plates 218 made of a heat resistant material such as quartz or SiC are supported in multiple stages below the boat 217. This configuration makes it difficult to transfer heat from the heater 207 to the seal cap 219. However, the present embodiment is not limited to the above-described form. For example, instead of installing the heat insulating plates 218 below the boat 217, a heat insulating tube configured as a cylindrical member made of a heat resistant material such as quartz or SiC may be installed.

A temperature sensor 263 serving as a temperature detector is installed in the reaction tube 203. Based on temperature information detected by the temperature sensor 263, an amount of electric power supplied to the heater 207 is adjusted such that the interior of the process chamber 201 has a desired temperature distribution. Similar to the nozzles 410 and 420, the temperature sensor 263 has an L-like shape and is installed along the inner wall of the reaction tube 203.

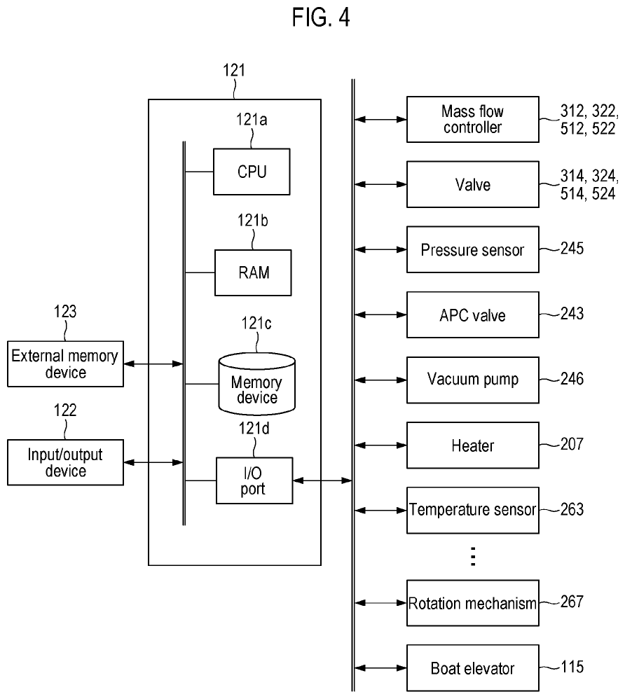

As illustrated in FIG. 4, a controller 121, which is a control part (control means), is configured as a computer including a central processing unit (CPU) 121a, a random access memory (RAM) 121b, a memory device 121c, and an I/O port 121d. The RAM 121b, the memory device 121c, and the I/O port 121d are configured to exchange data with the CPU 121a via an internal bus. An input/output device 122 formed of, for example, a touch panel or the like, is connected to the controller 121.

The memory device 121c is configured by, for example, a flash memory, a hard disk drive (HDD), or the like. A control program for controlling operations of a substrate processing apparatus, a process recipe in which procedures and conditions of substrate processing to be described later are written, a cleaning recipe in which procedures and conditions of a cleaning process to be described later are written, a purge recipe in which procedures and conditions of a purge process to be described later are written, etc., are readably stored in the memory device 121c. The process recipe functions as a program for causing the controller 121 to execute various steps in the substrate processing to be described later, to obtain an expected result. The cleaning recipe functions as a program for causing the controller 121 to execute various steps in the cleaning process to be described later, to obtain an expected result. The purge recipe functions as a program for causing the controller 121 to execute various steps in the purge process to be described later, to obtain an expected result. Hereinafter, the process recipe, the cleaning recipe, the purge recipe, and the control program may be generally and simply referred to as a “program.” When the term “program” is used herein, it may indicate a case of including the process recipe only, a case of including the cleaning recipe only, a case of including the purge recipe only, a case of including the control program only, or a case of including any combination of the process recipe, the cleaning recipe, the purge recipe, and the control program. The RAM 121b is configured as a memory area (work area) in which a program or data read by the CPU 121a is temporarily stored.

The I/O port 121d is connected to the MFCs 312, 322, 512, and 522, the valves 314, 324, 514, and 524, the APC valve 243, the pressure sensor 245, the vacuum pump 246, the heater 207, the temperature sensor 263, the rotation mechanism 267, the boat elevator 115, and so on.

The CPU 121a is configured to read and execute the control program from the memory device 121c. The CPU 121a also reads the process recipe, the cleaning recipe and the purge recipe from the memory device 121c according to an input of an operation command from the input/output device 122. Hereinafter, for the sake of convenience, these recipes are generally and simply referred to as a “recipe.” The CPU 121a is configured to control the flow rate adjusting operation of various kinds of gases by the MFCs 312, 322, 512, and 522, the opening/closing operation of the valves 314, 324, 514, and 524, the opening/closing operation of the APC valve 243, the pressure adjusting operation performed by the APC valve 243 based on the pressure sensor 245, the temperature adjusting operation of the heater 207 based on the temperature sensor 263, the actuating and stopping of the vacuum pump 246, the rotation and rotation speed adjusting operation of the boat 217 by the rotation mechanism 267, the moving up/down operation of the boat 217 by the boat elevator 115, and the like, according to contents of the read recipes.

The controller 121 may be configured by installing, on the computer, the aforementioned program stored in an external memory device 123 (for example, a magnetic tape, a magnetic disk such as a flexible disk or a hard disk, an optical disc such as a CD or a DVD, a magneto-optical disc such as an MO, a semiconductor memory such as a USB memory or a memory card, etc.). The memory device 121c or the external memory device 123 is configured as a non-transitory computer-readable recording medium. Hereinafter, the memory device 121c and the external memory device 123 may be generally and simply referred to as a “recording medium.” When the term “recording medium” is used herein, it may indicate a case of including the memory device 121c only, a case of including the external memory device 123 only, or a case of including both the memory device 121c and the external memory device 123. Furthermore, the program may be provided to the computer using a communication means such as the Internet or a dedicated line, instead of using the external memory device 123.

### (2) Film-Forming Process

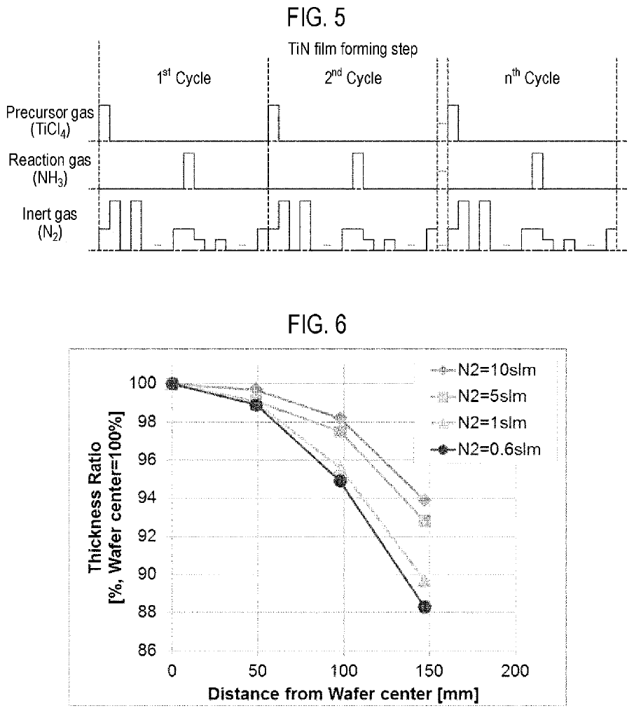

As one step of a process of manufacturing a semiconductor device using the above-described substrate processing apparatus, a sequence example of forming a film on a substrate will be described with reference to FIG. 5. In the following description, the operations of various parts constituting the substrate processing apparatus are controlled by the controller 121.

In the film-forming sequence illustrated in FIG. 5, a TiCl₄ gas as a precursor gas and an NH₃ gas as a reaction gas are supplied to a wafer 200 as a substrate accommodated in the process chamber 201 to form a titanium nitride film (TiN film) on the wafer 200.

When the term “wafer” is used in the present disclosure, it may refer to “a wafer itself” or “a wafer and a laminated body of certain layers or films formed on a surface of the wafer.” When the phrase “a surface of a wafer” is used in the present disclosure, it may refer to “a surface of a wafer itself” or “a surface of a certain layer formed on a wafer”. When the expression “forming a certain layer on a wafer” is used in the present disclosure, it may refer to “directly forming a certain layer on a surface of a wafer itself” or “forming a certain layer on a layer formed on a wafer”. When the term “substrate” is used in the present disclosure, it may be synonymous with the term “wafer.”

### (Wafer Charging and Boat Loading)

A plurality of wafers 200 are charged on the boat 217 (wafer charging). Then, as illustrated in FIG. 2, the boat 217 supporting the plurality of wafers 200 is lifted up by the boat elevator 115 to be loaded into the process chamber 201 (boat loading). In this state, the seal cap 219 seals the lower end of the manifold 209 through the O-ring 220.

### (Pressure Adjustment and Temperature Adjustment)

The interior of the process chamber 201 (that is, a space where the wafer 200 is placed) is vacuum-exhausted by the vacuum pump 246 so as to reach a desired pressure (degree of vacuum). At this time, the internal pressure of the process chamber 201 is measured by the pressure sensor 245. The APC valve 243 is feedback-controlled based on the measured pressure information (pressure adjustment). The vacuum pump 246 may be continuously activated at least until a processing of the wafers 200 is completed. In addition, the interior of the process chamber 201 is heated by the heater 207 to a desired temperature. In this operation, the amount of electric power supplied to the heater 207 is feedback-controlled based on the temperature information detected by the temperature sensor 263 (temperature adjustment) such that the interior of the process chamber 201 has a desired temperature distribution. The heating of the interior of the process chamber 201 by the heater 207 is continuously performed at least until the processing of the wafer 200 is completed. Subsequently, the rotation of the boat 217 and the wafer 200 is started by the rotation mechanism 267. The rotation of the boat 217 and the wafer 200 by the rotation mechanism 267 is continuously performed at least until the processing of the wafer 200 is completed.

### (TiN Film-Forming Step)

Thereafter, the following steps are sequentially performed.

### (Precursor Gas Supply Step)

The valve 314 is opened to allow a TiCl₄ gas, which is a precursor gas, to flow into the gas supply pipe 310. A flow rate of the TiCl₄ gas, which flows in the gas supply pipe 310, is adjusted by the MFC 312, and then the TiCl₄ gas is supplied from the gas supply holes 410a of the nozzle 410 into the process chamber 201 and is exhausted via the exhaust pipe 231. In this operation, the TiCl₄ gas is supplied to the wafer 200. At the same time, the valve 514 is opened to allow an inert gas such as a N₂ gas to flow into the gas supply pipe 510. A flow rate of the N₂ gas, which flows in the gas supply pipe 510, is adjusted by the MFC 512, and the N₂ gas is supplied into the process chamber 201 together with the TiCl₄ gas and is exhausted via the exhaust pipe 231. At this time, in order to prevent the TiCl₄ gas from entering the nozzle 420, the valve 524 is opened to allow a N₂ gas (backflow-prevention N₂ gas) to flow into the gas supply pipe 520. The N₂ gas is supplied into the process chamber 201 via the gas supply pipe 520 and the nozzle 420 and is exhausted via the exhaust pipe 231.

An example of the process conditions of this step is described as follows.

Internal pressure of process chamber 201: 1 to 1,330 Pa, specifically 40 to 1,100 Pa

TiCl₄ gas supply flow rate: 0.01 to 1.0 slm, specifically 0.1 to 0.5 slm

Total supply flow rate of N₂ gas supplied from nozzles 410 and 420: 0.5 to 5.0 slm, specifically 2.0 to 3.0 slm

Gas supply time: 1 to 60 seconds, specifically 1 to 10 seconds

Processing temperature: 200 to 700 degrees C., specifically 300 to 600 degrees C.

In the present disclosure, when the numerical range is, for example, 1 to 1,330 Pa, it means equal to or more than 1 Pa and equal to or less than 1,330 Pa. That is, 1 Pa and 1,330 Pa are included in the numerical range. The same applies to all numerical values described in the present disclosure, such as flow rate, time, temperature, and the like, in addition to the pressure.

Under the aforementioned conditions, by supplying the TiCl₄ gas to the wafer 200, a TiCl₄ adsorption layer, which is an adsorption layer of the TiCl₄ gas, is formed on the outermost surface of the wafer 200. It can be said that the TiCl₄ adsorption layer is a Ti-containing layer containing Ti.

### (Residual Gas Removal Step)

After the TiCl₄ adsorption layer is formed, the valve 314 is closed to stop the supply of TiCl₄ gas. At this time, with the APC valve 243 of the exhaust pipe 231 kept open, the interior of the process chamber 201 is vacuum-exhausted by the vacuum pump 246 so as to remove an unreacted TiCl₄ gas remaining in the process chamber 201 or a TiCl₄ gas that has contributed to the formation of the TiCl₄ adsorption layer from the process chamber 201. At this time, the valves 514 and 524 are controlled to adjust the total supply flow rate of the N₂ gas supplied into the process chamber 201 to be higher than the total supply flow rate of the N₂ gas in the precursor gas supply step. The N₂ gas acts as a substitution gas (purge gas) to enhance the effect of removing the unreacted TiCl₄ gas remaining in the process chamber 201 or the TiCl₄ gas that has contributed to the formation of the TiCl₄ adsorption layer from the process chamber 201. Further, the effect of removing (blowing) the TiCl₄ gas physically adsorbed on the wafer 200 from the wafer 200 to remove it from the process chamber 201 can be enhanced.

An example of the process conditions of this step is described as follows.

Total supply flow rate of N₂ gas supplied from nozzles 410 and 420: 0.1 to 15.0 slm, specifically 7.0 to 13.0 slm

Gas supply time: 2 to 30 seconds, specifically 4 to 10 seconds

If the total supply flow rate of the N₂ gas supplied from the nozzles 410 and 420 is lower than 0.1 slm, the unreacted TiCl₄ gas remaining in the process chamber 201 or the TiCl₄ gas that has contributed to the formation of the TiCl₄ adsorption layer and the TiCl₄ gas physically adsorbed on the wafer 200 cannot be sufficiently removed from the process chamber 201 and may remain in the process chamber 201. If the total supply flow rate of the N₂ gas supplied from the nozzles 410 and 420 is more than 15.0 slm, the internal pressure of the process chamber 201 becomes too high, so that a time for reducing the pressure is required before performing the subsequent reaction gas supply step, which may result in a decrease in throughput.

In this step, as illustrated in FIG. 5, the N₂ substitution (purge) by the supply of N₂ gas and the vacuum exhaust may be alternately repeated. By repeating them alternately, it becomes possible to more efficiently remove the unreacted TiCl₄ gas remaining in the process chamber 201 or the TiCl₄ gas that has contributed to the formation of the TiCl₄ adsorption layer and the TiCl₄ gas physically adsorbed on the wafer 200 from the process chamber 201. At that time, when the N₂ substitution (purge) is performed immediately after the supply of TiCl₄ gas is stopped and immediately before the supply of NH₃ gas to be described later is started, the effect of suppressing a turbulent flow of the TiCl₄ gas and the NH₃ gas can be enhanced. Further, by setting the total supply flow rate of the N₂ gas supplied from the nozzles 410 and 420 to be equal to the flow rate of the step of supplying the TiCl₄ gas immediately after the supply of TiCl₄ gas is stopped, the effect of suppressing the turbulent flow can be enhanced. By setting the total supply flow rate of the N₂ gas to be equal to the flow rate of the step of supplying the NH₃ gas immediately before the supply of NH₃ gas is started, the effect of suppressing the turbulent flow can be enhanced. Further, the N₂ substitution (purge) by the supply of N₂ gas may be continuously performed even during the vacuum exhaust. When the N₂ substitution is continuously performed, the process conditions for the N₂ substitution (purge) by the supply of N₂ gas are as described above.

### (Reaction Gas Supply Step)

After removing the residual gas in the process chamber 201, the valve 324 is opened to allow an NH₃ gas, which is a reaction gas, to flow into the gas supply pipe 320. A flow rate of the NH₃ gas, which flows in the gas supply pipe 320, is adjusted by the MFC 322, and then the NH₃ gas is supplied from the gas supply holes 420a of the nozzle 420 into the process chamber 201. The NH₃ gas supplied into the process chamber 201 is exhausted via the exhaust pipe 231. In this operation, the NH₃ gas is supplied to the wafer 200. At the same time, the valve 524 is opened to allow an inert gas such as a N₂ gas to flow into the gas supply pipe 520. A flow rate of the N₂ gas, which flows in the gas supply pipe 520, is adjusted by the MFC 522, and the N₂ gas is supplied into the process chamber 201 together with the NH₃ gas and is exhausted via the exhaust pipe 231. At this time, in order to prevent the NH₃ gas from entering the nozzle 410, the valve 514 is opened to allow a N₂ gas (backflow-prevention N₂ gas) to flow into the gas supply pipe 510. The N₂ gas is supplied into the process chamber 201 via the gas supply pipe 510 and the nozzle 410 and is exhausted via the exhaust pipe 231.

An example of the process conditions of this step is described as follows.

Internal pressure of process chamber 201: 1 to 1,330 Pa, specifically 50 to 1,110 Pa

Total supply flow rate of N₂ gas supplied from nozzles 410 and 420: 0.5 to 5.0 slm, specifically 1.0 to 3.0 slm

Gas supply time: 1 to 120 seconds, specifically 5 to 60 seconds

Other process conditions such as the processing temperature are the same as the process conditions in the precursor gas supply step.

At this time, the gas flowing in the process chamber 201 is only the NH₃ gas and the N₂ gas. The NH₃ gas makes a substitution reaction with at least a portion of the TiCl₄ adsorption layer formed on the wafer 200 in the precursor gas supply step. During the substitution reaction, Ti contained in the TiCl₄ adsorption layer and N contained in the NH₃ gas are combined to form a TiN layer containing Ti and N on the wafer 200.

### (Residual Gas Removal Step)

After forming the TiN layer, the valve 324 is closed to stop the supply of NH₃ gas. Then, a gas and the like remaining in the process chamber 201 are removed from the process chamber 201 by the same processing procedure as the residual gas removal step after the precursor gas supply step.

At this time, the valves 514 and 524 are controlled to adjust the total supply flow rate of the N₂ gas supplied into the process chamber 201 to be lower than the total supply flow rate of the N₂ gas in the reaction gas supply step. That is, in the residual gas removal step, the total supply flow rate of the N₂ gas supplied into the process chamber 201 is adjusted to include a timing at which the total supply flow rate of the N₂ gas becomes lower than the total supply flow rate of the N₂ gas in the reaction gas supply step. The N₂ gas acts as a substitution gas (purge gas) to enhance the effect of removing an unreacted NH₃ gas remaining in the process chamber 201 or a NH₃ gas that has contributed to the formation of the TiN adsorption layer, and by-products (for example, HCl, etc.) from the process chamber 201. In particular, by adjusting the total supply flow rate of the N₂ gas supplied into the process chamber 201 to be lower than the total supply flow rate of the N₂ gas in the reaction gas supply step, the effect of removing the NH₃ gas can be further enhanced in the outer peripheral portion of the wafer 200. Further, the NH₃ gas physically adsorbed on the wafer 200 can be more removed (blown) from the outer peripheral portion of the wafer 200 to enhance the effect of removing it from the process chamber 201. At the same time, by retaining the unreacted NH₃ gas or the NH₃ gas that has contributed to the formation of the TiN layer in the central portion of the wafer 200 and reacting the NH₃ gas with the TiCl₄ adsorption layer or the TiN layer in the central portion, a TiN layer having a convex distribution can be formed.

An example of the process conditions of this step is described as follows.

Total supply flow rate of N₂ gas supplied from nozzles 410 and 420: 0.1 to 5.0 slm, specifically 0.6 to 3.0 slm

Gas supply time: 2 to 30 seconds, specifically 4 to 10 seconds

If the total supply flow rate of the N₂ gas supplied from the nozzles 410 and 420 is less than 0.1 slm, the unreacted NH₃ gas remaining in the process chamber 201 or the NH₃ gas that has contributed to the formation of the TiN adsorption layer, and by-products cannot be sufficiently removed from the process chamber 201 and may remain in the process chamber 201. If the total supply flow rate of the N₂ gas supplied from the nozzles 410 and 420 is more than 10.0 slm, a difference in the film thickness distribution between the outer peripheral portion of the wafer 200 and the central portion thereof cannot be made, and thus the desired in-plane uniformity cannot be obtained.

In this step, as illustrated in FIG. 5, the N₂ substitution (purge) by the supply of N₂ gas and the vacuum exhaust may be alternately repeated. By repeating them alternately, it becomes possible to more efficiently remove the unreacted NH₃ gas remaining in the process chamber 201 or the NH₃ gas that has contributed to the formation of the TiN adsorption layer, by-products, and the NH₃ gas physically adsorbed on the wafer 200 from the process chamber 201. At that time, when the N₂ substitution (purge) is performed at a timing immediately after the supply of NH₃ gas is stopped (i.e., the initial N₂ substitution or the initial supply of inert gas) and immediately before the supply of TiCl₄ gas in the next cycle is started (i.e., the last N₂ substitution or the last supply of inert gas), the effect of suppressing a turbulent flow of the TiCl₄ gas and the NH₃ gas can be enhanced. Further, by adjusting the total supply flow rate of the N₂ gas supplied from the nozzles 410 and 420 to be equal to the total supply flow rate of the reaction gas supply step at a timing immediately after the supply of NH₃ gas is stopped, the effect of suppressing the turbulent flow can be enhanced. After the N₂ substitution is performed a predetermined number of times, the total supply flow rate of the N₂ gas supplied into the process chamber 201 is adjusted to be lower than the total supply flow rate of the N₂ gas in the reaction gas supply step. Thereafter, at a timing immediately before the supply of TiCl₄ gas is started, by adjusting the total supply flow rate of the N₂ gas to be equal to the total supply flow rate of the reaction gas supply step, the effect of suppressing the turbulence flow can be enhanced. Further, the N₂ substitution (purge) by the supply of N₂ gas may be continuously performed even during the vacuum exhaust. When the N₂ substitution is continuously performed, the process conditions for the N₂ substitution (purge) by the supply of N₂ gas are as described above. At that time, the total supply flow rate of the N₂ gas supplied into the process chamber 201 may be adjusted to be continuously supplied at a flow rate lower than the total supply flow rate of the reaction gas supply step. Alternatively, the total supply flow rate of the N₂ gas supplied into the process chamber 201 may be adjusted to be equal to the total supply flow rate of the reaction gas supply step at a timing immediately after the supply of the NH₃ gas is stopped, to be equal to the total supply flow rate of the precursor gas supply step at a timing immediately after the supply of the TiCl₄ gas in the next cycle is started, and to be lower than the total supply flow rate of the reaction gas supply step at other timings.

### (Performed Predetermined Number of Times)

A TiN film having a predetermined thickness is formed on the wafer 200 by performing a cycle a predetermined number of times (n times, n is an integer of 1 or more), the cycle sequentially performing the above steps in time-division. The value of n is appropriately selected according to the film thickness required in the finally formed TiN film. That is, the number of times for performing each of the above processes is determined according to the target film thickness. The above cycle may be repeated multiple times. The thickness of the TiN film is, for example, 0.1 to 300 nm, specifically 0.8 to 200 nm.

### (Purge and Atmospheric Pressure Return)

The valves 514 and 524 are opened to supply a N₂ gas into the process chamber 201 from each of the gas supply pipes 510 and 520, and the N₂ gas is exhausted via the exhaust pipe 231. The N₂ gas acts as a purge gas, whereby the interior of the process chamber 201 is purged with an inert gas, so that a gas and by-products remaining in the process chamber 201 are removed from the interior of the process chamber 201 (purge). After that, the internal atmosphere of the process chamber 201 is substituted with an inert gas (inert gas substitution) and the internal pressure of the process chamber 201 is returned to an atmospheric pressure (atmospheric pressure return).

### (Boat Unloading and Wafer Discharging)

After that, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat unloading, the processed wafers 200 are discharged from the boat 217 (wafer discharging).

### (3) Effects According to the Present Embodiment

According to the present embodiment, one or more effects set forth below may be achieved.

(a) When a thin film is formed using a precursor gas and a reaction gas, by adjusting and optimizing the supply flow rate of an inert gas when the reaction gas is substituted, it is possible to obtain a desired film thickness distribution by changing a film thickness distribution in the central portion of the substrate and the outer peripheral portion thereof.

(b) It is possible to improve the electrical characteristics by obtaining a desired film thickness distribution by changing a film thickness distribution in the central portion of the substrate and the outer peripheral portion thereof.

(c) By obtaining a desired film thickness distribution by changing a film thickness distribution in the central portion of the substrate and the outer peripheral portion thereof, it is possible to take measures against the loading effect in the substrate surface which becomes remarkable when a film is formed on a patterned substrate having a large surface area.

(d) By lowering the supply flow rate of an inert gas in the substitution step after the reaction gas supply, it is possible to obtain a thin film having a convex film thickness distribution in which the outer peripheral portion of the substrate is thin and the central portion thereof is thick.

(e) When the substitution (purge) with an inert gas is performed immediately after stopping the supply of the reaction gas and immediately before starting the supply of the precursor gas in the next cycle, the effect of suppressing the turbulent flow can be enhanced.

(f) By setting the flow rate of an inert gas supplied immediately after stopping the supply of the reaction gas to be equal to the flow rate of the inert gas at the time of supply of the reaction gas, the effect of suppressing the turbulence flow can be enhanced.

(g) By setting the flow rate of an inert gas supplied immediately before starting the supply of the precursor gas to be equal to the flow rate of the inert gas at the time of supply of the precursor gas, the effect of suppressing the turbulence flow can be enhanced.

FIG. 6 shows, as an experimental result of the present embodiment, a result obtained by changing the supply flow rate of the inert gas supplied in the residual gas removal step after the reaction gas is supplied. FIG. 6 shows the film thickness ratio (Thickness Ratio) of the central portion of the wafer 200 to a distance from the central portion of the wafer 200 (Distance from Wafer center). The film thickness ratio of the central portion of the wafer 200 is a correction value reduced with the value of the central portion of the wafer 200 as 100%. It can be seen from FIG. 6 that the in-plane film thickness distribution changes to a convex shape as the supply flow rate of the inert gas decreases.

### Other Embodiments

Some embodiments of the present disclosure have been specifically described above. However, the present disclosure may not be limited to the above-described embodiments, and various changes can be made without departing from the gist of the present disclosure.

In addition, although the N₂ gas is exemplified as the inert gas in the above-described embodiments, it may be possible to use, as the inert gas, for example, a rare gas such as an Ar gas, a He gas, a Ne gas, a Xe gas, or the like, in addition to the N₂ gas.

Further, for example, although the TiO film using the Ti element as the film formed on the substrate is exemplified in the above-described embodiments, it may be possible to suitably apply to a case of forming an oxide film, a nitride film, and a carbide film, which contain elements other than Ti, such as tantalum (Ta), tungsten (W), cobalt (Co), yttrium (Y), ruthenium (Ru), aluminum (Al), hafnium (Hf), zirconium (Zr), molybdenum (Mo), silicon (Si), and the like, or a composite film thereof, in addition to the TiO film.

In the case of forming a film containing the above-mentioned elements, as the precursor gas, it may be possible to use, for example, precursor gases containing halides and organic compounds such as tetrakisdimethylamino titanium (Ti[N(CH₃)₂]₄), tantalum pentachloride (TaCl₅), pentaethoxytantalum (Ta(OC₂H₅)₅), tungstenhexafluoride (WF₆), bis(tertiarybutylimino)bis(tertiarybutylamino)tungsten ((C₄H₉NH)₂W(C₄H₉N)₂), cobaltichloride (CoCl₂), bis(ethylcyclopentadienyl)cobalt (C₁₄H₁₈Co), yttriumtrichloride (YCl₃), tris(butylcyclopentadienyl)yttrium (Y(C₅H₄CH₂(CH₂)₂CH₃)₃), rutheniumtrichloride (RuCl₃), bis(ethylcyclopentadienyl)ruthenium (C₁₄H₁₈Ru), aluminumtrichloride (AlCl₃), trimethylaluminum ((CH₃)₃Al), hafniumtetrachloride (HfCl₄), tetrakisethylmethylaminohafnium (Hf[N(CH₃)CH₂CH_{3]4}), zirconiumtetrachloride (ZrCl₄), tetrakisethylmethylaminozirconium (Zr[N(CH₃)CH₂CH₃]₄), monosilane (SiH₄), dichlorosilane (SiH₂Cl₂), trisdimethylaminosilane (SiH[N(CH₃)₂]₃, and the like, in addition to the TiCl₄.

As the reaction gas, it may be possible to use, for example, nitric oxide (N₂O), ozone (O₃), oxygen (O₂), water vapor (H₂O), hydrogen peroxide (H₂O₂), a mixed gas of O₂+H₂, water vapor (H₂O gas), propylene (C₃H₆), and the like, and those obtained by plasma-exciting them, in addition to ammonia (NH₃).

In the above-described embodiments, an example in which the reaction tube has a single tube structure has been described. However, the reaction tube may have a double tube structure having an inner reaction tube (inner tube) and an outer reaction tube (outer tube) provided outside thereof.

The process recipe used for forming these various thin films (a program in which a processing procedure and process conditions of the film-forming process are described), the cleaning recipe used for removing deposits including these various thin films (a program in which a processing procedure and process conditions of the cleaning process are described), and a purge recipe used for removing residual halogen elements (a program in which a processing procedure and process conditions of the purging process are described) may be prepared individually (in plural) according to the contents of the film-forming process, and the cleaning process, and the purging process (film type, composition ratio, film quality, film thickness, etc. of a thin film to be formed or removed). Then, when starting a various kinds of processes, a proper recipe may be appropriately selected from the plurality of recipes according to the processing contents. Specifically, the plurality of recipes individually prepared according to the processing contents may be stored (installed) in advance in the memory device 121c included in the substrate processing apparatus via an electric communication line or a recording medium (the external memory device 123) in which the recipes are recorded. Then, when starting the film-forming process, the cleaning process, and the purging process, the CPU 121a included in the substrate processing apparatus may appropriately select a proper recipe from the plurality of recipes stored in the memory device 121c according to the processing contents. With such a configuration, it is possible to form and remove thin films of various film types, composition ratios, film qualities, and film thicknesses in a versatile and reproducible manner with one substrate processing apparatus. In addition, it is possible to reduce an operator's burden (the input burden of the processing procedure, the process conditions, etc.) and to quickly start various processes while avoiding operational mistakes.

The above-mentioned process recipe, cleaning recipe, and purge recipe may not be limited to newly-prepared ones but may be prepared, for example, by modifying existing recipes that are already installed in the substrate processing apparatus. Once the recipes are modified, the modified recipes may be installed in the substrate processing apparatus via a telecommunication line or a recording medium storing the recipes. In addition, the existing recipes already installed in the substrate processing apparatus may be directly modified by operating the input/output device 122 of the substrate processing apparatus.

In addition, the above embodiments, modifications and so on may be used in proper combination. The process conditions used in this case may be, for example, the same as those of the above embodiments.

According to the present disclosure in some embodiments, it is possible to provide a technique for controlling the in-plane film thickness distribution of a thin film according to the surface area and the electrical characteristics of a substrate when forming the thin film on the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device, comprising:
(a) supplying a precursor gas and an inert gas to a substrate in a process chamber;
(b) removing the precursor gas remaining in the process chamber by supplying the inert gas to the substrate in a state where the supply of the precursor gas is stopped;
(c) supplying a reaction gas and the inert gas to the substrate; and
(d) removing the reaction gas remaining in the process chamber by supplying the inert gas to the substrate in a state where the supply of the reaction gas is stopped,
wherein (d) includes a timing at which a flow rate of the inert gas becomes lower than a flow rate of the inert gas supplied in (c).

2. The method of claim 1, wherein in (d), the inert gas is supplied at a flow rate lower than the flow rate of the inert gas supplied in (c) at least when the inert gas is supplied at an initial time, and the inert gas is supplied at a flow rate identical to a flow rate of the inert gas supplied in (a) at least when the inert gas is supplied at a last time.

3. The method of claim 1, wherein (a) to (d) are sequentially performed a plurality of times.

4. The method of claim 2, wherein (a) to (d) are sequentially performed a plurality of times.

5. The method of claim 2, wherein (d) includes a timing at which the flow rate of the inert gas becomes equal to the flow rate of the inert gas supplied in (a).

6. The method of claim 3, wherein (d) includes a timing at which the flow rate of the inert gas becomes equal to the flow rate of the inert gas supplied in (a).

7. The method of claim 4, wherein (d) includes a timing at which the flow rate of the inert gas becomes equal to the flow rate of the inert gas supplied in (a).

8. The method of claim 1, wherein the supply and vacuum exhaust of the inert gas are alternately performed a plurality of times in (d).

9. The method of claim 8, wherein in (d), when alternately performing the supply and the vacuum exhaust of the inert gas the plurality of times, the inert gas is supplied at a flow rate lower than the flow rate of the inert gas supplied in (c) at least when the inert gas is supplied at an initial time, and the inert gas is supplied at a flow rate identical to the flow rate of the inert gas supplied in (a) at least when the inert gas is supplied at a last time.

10. The method of claim 1, wherein in (d), the inert gas is continuously supplied at a flow rate lower than the flow rate of the inert gas supplied in (c).

11. The method of claim 1, wherein (b) includes a timing at which a flow rate of the inert gas becomes higher than a flow rate of the inert gas supplied in (a).

12. The method of claim 1, wherein in (b), the supply and vacuum exhaust of the inert gas are alternately performed a plurality of times.

13. A substrate processing apparatus comprising:
a process chamber in which a substrate is accommodated;
a gas supply system configured to supply a precursor gas, a reaction gas, and an inert gas into the process chamber; and
a controller configured to be capable of controlling the gas supply system so as to perform a process on the substrate accommodated in the process chamber, the process including:
(a) supplying the precursor gas and the inert gas to the substrate in the process chamber;
(b) removing the precursor gas remaining in the process chamber by supplying the inert gas to the substrate in a state where the supply of the precursor gas is stopped;
(c) supplying the reaction gas and the inert gas to the substrate; and
(d) removing the reaction gas remaining in the process chamber by supplying the inert gas to the substrate in a state where the supply of the reaction gas is stopped,
wherein (d) includes a timing at which a flow rate of the inert gas becomes lower than a flow rate of the inert gas supplied in (c).

14. The substrate processing apparatus of claim 13, wherein in (d), the controller is configured to be capable of controlling the gas supply system such that the inert gas is supplied at a flow rate lower than the flow rate of the inert gas supplied in (c) at least when the inert gas is supplied at an initial time, and the inert gas is supplied at a flow rate identical to a flow rate of the inert gas supplied (a) at least when the inert gas is supplied at a last time.

15. The substrate processing apparatus of claim 14, wherein the controller is configured to be capable of controlling the gas supply system such that (d) includes a timing at which a flow rate of the inert gas becomes equal to the flow rate of the inert gas supplied in (a).

16. The substrate processing apparatus of claim 13, wherein in (d), the controller is configured to be capable of controlling the gas supply system such that the supply and vacuum exhaust of the inert gas are alternately performed a plurality of times.

17. A non-transitory computer-readable recording medium storing a program that causes, by a computer, a substrate processing apparatus to perform a process on a substrate in a process chamber of the substrate processing apparatus, the process comprising:
(a) supplying a precursor gas and an inert gas to the substrate in the process chamber;
(b) removing the precursor gas remaining in the process chamber by supplying the inert gas to the substrate in a state where the supply of the precursor gas is stopped;
(c) supplying a reaction gas and the inert gas to the substrate; and
(d) removing the reaction gas remaining in the process chamber by supplying the inert gas to the substrate in a state where the supply of the reaction gas is stopped,
wherein (d) includes a timing at which a flow rate of the inert gas becomes lower than a flow rate of the inert gas supplied in (c).

18. The non-transitory computer-readable recording medium of claim 17, wherein in (d), the inert gas is supplied at a flow rate lower than the flow rate of the inert gas supplied in (c) at least when the inert gas is supplied at an initial time, and the inert gas is supplied at a flow rate identical to a flow rate of the inert gas supplied in (a) at least when the inert gas is supplied at a last time.

19. The non-transitory computer-readable recording medium of claim 18, wherein (d) includes a timing at which a flow rate of the inert gas becomes equal to the flow rate of the inert gas supplied in (a).

20. The non-transitory computer-readable recording medium of claim 17, wherein in (d), the supply and vacuum exhaust of the inert gas are alternately performed a plurality of times.
